(19) United States
(12) Patent Application Publication
(10) Pub. No.: US 2008/0247908 A1
(43) Pub. Date: Oct. 9, 2008

(54) Sensor Chip for a Biosensor

(75) Inventor: Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/995,717

(22) PCT Filed: Jul. 13, 2006
(86) PCT No.: PCT/IB06/52383

§ 371 Date: Jan. 15, 2008

(30) Foreign Application Priority Data
Jul. 21, 2005 (EP) 05106683.5

(51) Int. Cl. B01J 19/00; H01L 29/00; H01L 29/82

(52) U.S. Cl. 422/68.1; 257/414; 257/421; 257/E29.323; 257/E29.001

(57) ABSTRACT

The invention relates to a microchip (10) and a microfluidic biosensor (200) comprising such a microchip (10) as a sensor. The microchip (10) may particularly comprise coupling circuits on its sensitive side for generating and sensing magnetic fields. The circuits are connected by feedthrough connections (VIAs) to terminals (204) at the back side of the microchip (10) for external bonding. The front side of the sensor chip (10) can thus be kept freely accessible from a sample chamber (206). The back side of the sensor chip (10) may particularly be flip-chip bonded to a signal processing chip (20), which is connected to external circuits by a flex foil (202).

The invention relates to a microelectronic chip with coupling circuits on a substrate that are adapted to perform and process wireless physical interactions. Moreover, it is related to a microfluidic device comprising such a microchip.

From the WO 2005/010543 A1 and WO 2005/010542 A2 a microchip is known which may for example be used in a microfluidic biosensor for the detection of biological molecules labeled with magnetic beads. The sensor chip is provided with coupling circuits comprising wires for the generation of a magnetic field and Giant Magneto Resistances (GMR) for the detection of stray fields generated by magnetized beads. The coupling circuits are fabricated at a “sensitive side” of the chip on a semiconductor substrate, and each sensor chip is attached behind a hole in the wall of a microfluidic channel with its sensitive side facing the channel. A disadvantage of these known devices is that the sample fluid has to dive into a recess to reach the sensitive chip surface. This may create regions of low or stagnant flow and generally impairs the measurement.

Based on this situation it was an object of the present invention to provide means that particularly allow the construction of an improved microfluidic device of the kind described above.

This object is achieved by a microchip according to claim 1 and by a microfluidic device according to claim 8. Preferred embodiments are disclosed in the dependent claims.

According to its first aspect, the invention relates to a microelectronic chip or “microchip” comprising the following components:

a) a substrate;
b) coupling circuits on a front side of the substrate, the coupling circuits being adapted to perform and process a wireless physical interaction;
c) at least one electrical feedthrough passage, which is simply called “VIA” in the following, that is disposed or embedded in the substrate and that electrically connects a component of the coupling circuits to an externally accessible terminal which is disposed at a location remote from the front side of the substrate, i.e. not in the same plane as the front side of the substrate.

The substrate on which the coupling circuits are disposed or fabricated may particularly be one of the known semiconductor materials like silicon Si, GaAs, polymers, SiO₂, non-magnetic stainless steel having an isolation layer or mixtures thereof. Typically, there is an intimate contact and junction between substrate and coupling circuits, with the circuits for example being generated by doping in the surface layers of the substrate and/or by deposition of material on said surface.

The physical interaction that the coupling circuits are able to perform may particularly comprise the generation and/or detection of electromagnetic fields, wherein this term shall comprise pure magnetic fields and pure electric fields. It may however also involve other physical phenomena (e.g. thermal conduction). Typically, these interactions are limited to short distances in the order of the extensions of the microchip, particularly in the order the thickness of the chip or its components, which may range from zero up to 100 μm, preferably up to 10 μm, most preferably up to 2 μm. It should be noted that the coupling circuits are also capable to process the physical interactions. This shall quite generally mean that they have a controllable influence on these interactions and/or that they are influenced by the interactions in a controllable way. This distinguishes the coupling circuits from usual circuits of a microchip, which are of course also subject to physical interactions, but wherein said interactions are only (undesired) interferences and effectively without influence on the normal processing function of the circuits. In contrast to this, the coupling circuits are particularly designed to exploit the experienced wireless physical interactions.

Known microchips consist of a semiconductor substrate with the corresponding circuits on its “front side”, wherein bond pads are provided on said front side to which wires of external connections can be bonded. The resulting bonding sites are however relatively bulky and therefore disadvantageous in applications where the front side of the microchip shall be readily accessible, for instance in the biosensor applications mentioned above. A microchip of the kind described above solves these problems by providing electrical feedthrough passages or VIAs in the substrate which make the circuits on the front side of the microchip electrically accessible through terminals at a location remote from the front side, where more or less bulky connections do not hinder.

The coupling circuits may particularly be designed in such a way that they implement a sensor, preferably a capacitive sensor, a light sensor, an electrical current sensor, a voltage sensor and/or a magneto-electric sensor. In sensor applications, it is often necessary to bring coupling circuits of the sensors as close as possible to an object. The proposed microchip allows such close contacting as the access to its sensitive front side is not hindered by bulky external connections.

According to a particular embodiment of the invention, the coupling circuits comprise circuits for the generation of an electromagnetic field, for example wires through which (AC or DC) currents can be directed to generate (alternating or static) magnetic fields. Additionally or alternatively, the coupling circuits may comprise circuits for the detection of an electromagnetic field, particularly a magnetic sensor device like a Giant Magneto Resistance (GMR) for the detection of magnetic fields. If both circuits for the generation and the detection of electromagnetic fields are provided, the microchip is especially apt for biosensor applications of the kind referred to above.

The terminal of the at least one VIA is preferably located at the back side of the substrate or at a lateral side of the substrate. Both possibilities can be realized with VIAs that extend substantially perpendicular through the (substantially planar) substrate and that can be readily fabricated.

According to a further development of the microchip, the at least one terminal of the associated VIA is bonded to a second microchip, i.e. directly connected to the bond pads of the second microchip in a flip-chip technology without intermediate wires. The second microchip may particularly be a signal processing chip for the pre-processing and/or post-processing of signals from the coupling circuits of the first microchip. The direct connection between first and second microchip has the advantage that long connection lines are avoided and a large bandwidth can thus be realized.

The aforementioned second microchip may optionally also comprise at least one electrical feedthrough passage or VIA. Thus the front side of the second microchip can be bonded to the terminals of the VIAs of the first microchip, and the second microchip can be externally contacted at the terminals of its own VIAs, i.e. from its back side.

The thickness of the microchip is optionally limited to a range from 10 μm to 500 μm, most preferably from 10 μm to 100 μm, allowing its integration into microfluidic channels.

The invention further relates to a microfluidic device with at least one sample chamber in which liquid, gaseous or solid samples can be provided, particularly to a biosensor for the investigation of biological samples, which comprises a microchip of the kind described above. This means that the microfluidic device comprises a microchip with coupling circuits for wireless physical interactions on the front side of a substrate and with VIAs leading from said circuits to terminals outside the front side of the substrate. The free accessibility of the front side of the microchip can be exploited in such a microfluidic device in various ways to improve the contact between the microchip and a sample in the sample chamber of the device.

According to a first embodiment of the microfluidic device, the associated microchip is attached to the inner side of a wall of the sample chamber of the device. Electrical connections to the microchip can then be provided from the back side or a lateral side of the substrate using the VIAs and thus do not impair the free access to the front side of the microchip.

In the aforementioned embodiment, a mechanical support is preferably disposed between the microchip and the respective wall of the sample chamber. Such a support stabilizes the arrangement and protects the microchip from breakage, though it may not be necessary for the attachment of the chip to the wall (which is typically achieved by bonding).

According to a second embodiment of the microfluidic device, the microchip is integrated into a wall of the sample chamber. In this case, the microchip does not protrude into the sample chamber, thus leaving the microfluidic properties of the sample chamber completely unchanged.

In a preferred embodiment of the invention, at least one wall of the sample chamber of the microfluidic device is a molded interconnection device (MID) or a flex foil. In this case, the chip can be directly bonded to said wall for electrical connection. If necessary, the flex foil may be provided with an extra stiffness.

According to a further development, the microfluidic device may comprise the least one second microchip which is connected to the first microchip directly (e.g. by flip-chip bonding) or via electrical leads. The second microchip may particularly be a signal processing chip for pre- or post-processing of data from the coupling circuits. A direct bonding has the advantage to avoid the losses and signal corruption of long electrical leads, thus allowing a higher signal bandwidth.

These and other aspects of the invention will be apparent from and elucidated with reference to the embodiment(s) described hereinafter.

In the following the invention is described by way of example with the help of the accompanying schematic drawings in which:

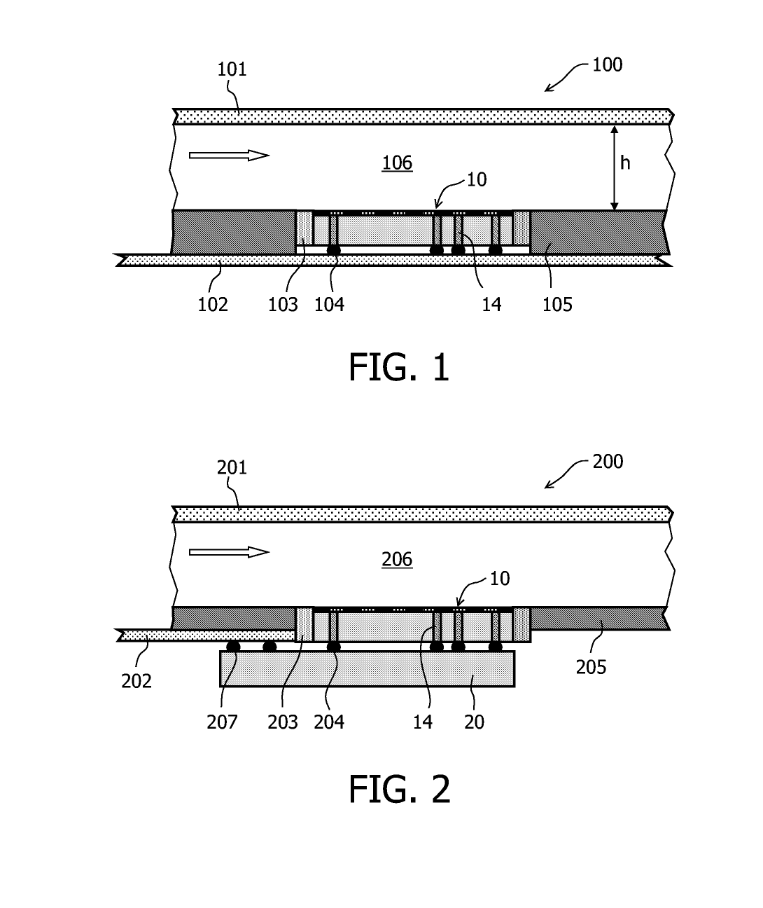

FIGS. 1-7 show in a side view sections through a fluid channel of microfluidic biosensors with a sensor chip according to the present invention, and in particular:

FIG. 1 shows the microchip integrated into the bottom wall;

FIG. 2 shows the microchip directly bonded to a signal processing chip;

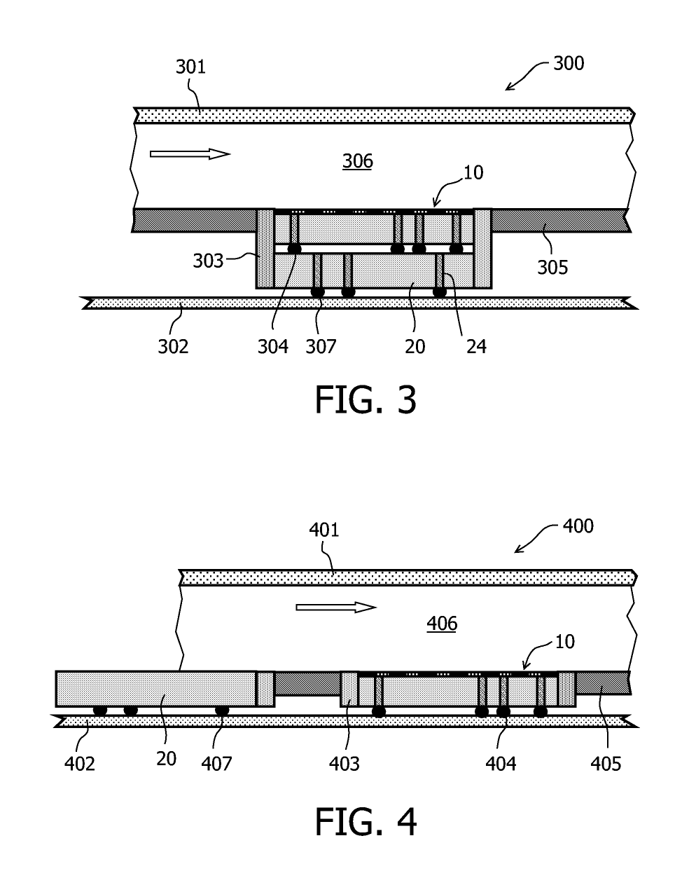

FIG. 3 shows a variant of FIG. 2, wherein the signal processing chip comprises VIAs;

FIG. 4 shows a variant of FIG. 2, wherein the signal processing chip is connected to the sensor chip by a flex foil;

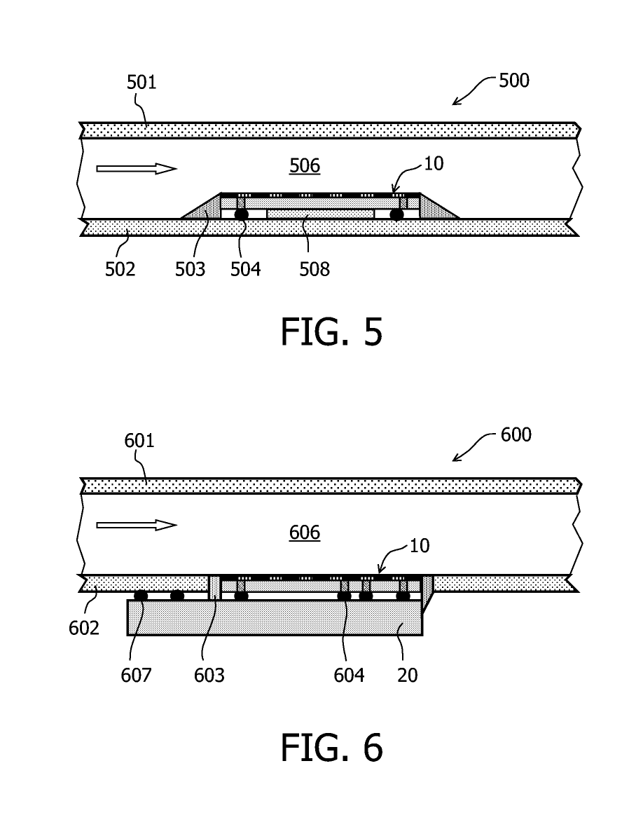

FIG. 5 shows a microchip of reduced thickness inside a channel;

FIG. 6 shows a variant of FIG. 5, wherein the microchip is integrated into the bottom wall of the fluid channel and bonded to a signal processing chip;

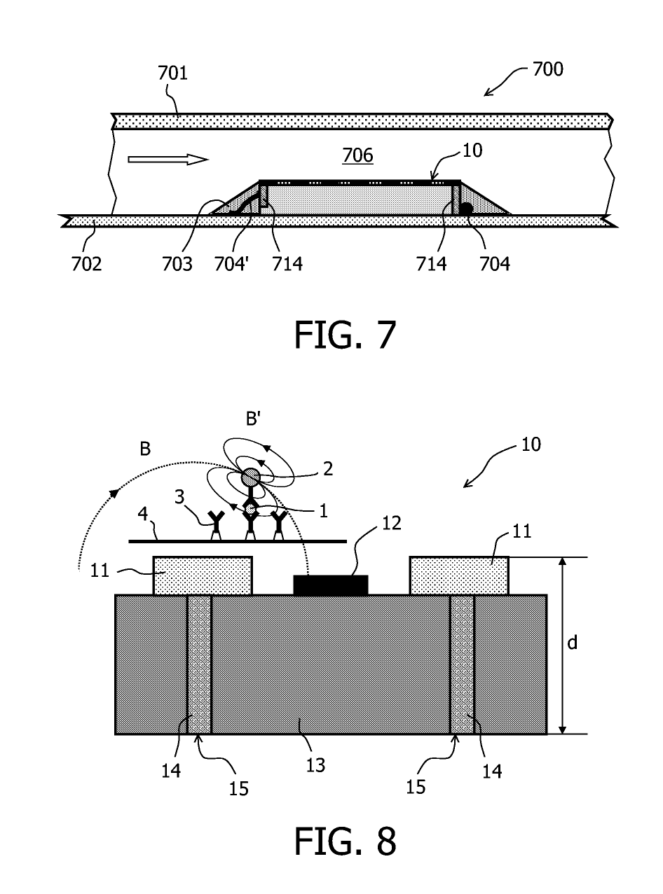

FIG. 7 shows a variant of FIG. 5, wherein the VIAs of the microchip extend along and are contacted at the lateral sides of the microchip;

FIG. 8 shows a section through a sensor chip according to the present invention

Like reference numbers in the Figures refer to identical or similar components.

The following description of the invention is based on the example of a magnetic biosensor or biochip, though the invention is not limited thereto and can be applied to all sensors that require electrical connections, e.g. capacitive sensors, electronic light detectors, Ampere metric sensors, Volta metric sensors, magneto-electric sensors, etc.

Magneto-resistive biochips have promising properties for bio-molecular diagnostics, in terms of sensitivity, specificity, integration, ease of use, and costs. Examples of such biochips are for example described in WO 2003/054566, WO 2003/054523, WO 2005/010542 A2, WO 2005/010543 A1 or Rife et al. (Sens. Act. A vol. 107, p. 209 (2003)), which are incorporated into the present application by reference. The known biosensors have however several drawbacks, namely:
Only a small amount of the main liquid flow will reach the sensor surface as it is located in a cavity of the sample chamber wall.
A large liquid flow is required to remove air bubbles from the cavity. (These first two problems increase the amount of required antigens and magnetic beads, they complicate washing and fluid handling in the cartridge and they are not compatible with an in-expensive, easy to use and disposable biosensor.)
The relatively long connection wires from the sensor to the pre-processing circuitry limit the electrical bandwidth of the detection system and may introduce noise. Due to the process incompatibility between the GMR sensor material (Cu) and CMOS it is not possible to realize both functions in the same IC process. As a result two chips (system-on-chip: GMR+CMOS) must be connected. In the current geometry it is not possible to connect said chips close enough to the sensor in order to implement a large bandwidth, e.g. of more than 1 GHz, which is required to distinguish between magnetic beads properties (barcoding).

The origin of these drawbacks is quite principally: the sensitive surface of the sensor and the sensor connections are located in the same plane. A solution for this problem is to contact the sensor at a plane, which is not its sensitive plane. Several embodiments of this approach will be described in the following.

FIG. 8 schematically shows a microchip or sensor chip 10 which allows the implementation of the aforementioned idea. As in sensor chips known from the state-of-the-art, the chip 10 comprises a substrate layer (or short “substrate”) 13 which may be a typical semiconductor like silicon. On the upper side of the substrate 13 (called “front side” in the following) are coupling circuits comprising two metal wires 11 and a Giant Magneto Resistance (GMR) 12. A biosensor consisting of an array of (e.g. 100) such sensor chips 10 for the detection of superparamagnetic beads may be used to simultaneously measure the concentration of a large number of different biological target molecules 1 (e.g. protein, DNA, amino acids) in a solution (e.g. blood or saliva). In one possible example of a binding scheme, the so-called “sandwich assay”, this is achieved by providing a binding surface 4 with first antibodies 3, to which the target molecules 1 may bind. Superparamagnetic beads 2 carrying second antibodies may then attach to the bound target molecules 1. A current flowing in the wires 11 then generates a magnetic field B, which then magnetizes the super-paramagnetic beads 2. The stray field B′ from the superparamagnetic beads 2 introduces an in-plane magnetization component in the GMR 12, which results in a measurable resistance change.

According to the present invention electrically conducting feedthrough passages 14 (in the following called “VIAs”) are provided within the substrate 13 of the sensor chip 10. These VIAs 14 connect the electrical wires 11 on the front side of the sensor chip 10 to terminals 15 on the back side of the microchip. The front side of the microchip can therefore be kept free from bulky electrical connections, which are instead moved to the back side.

FIG. 1 shows a first embodiment of a microfluidic biosensor 100 which incorporates are sensor chip 10 of the kind described above (FIG. 8). A microfluidic channel with a sample chamber 106 of height h (typically h=70-100 μm) is formed between a cartridge cover 101 and a channel bottom wall 105. The sensor chip 10 is integrated into a hole in the bottom wall 105 and fixed in a watertight way, for example by sufficient tight mechanical clamping or, as the shown in the Figure, with the help of a glue 103 (e.g. silicon kit). The integration of the sensor chip 10 in the bottom 105 with its sensitive front side (comprising the coupling circuits 11, 12 of FIG. 8) in line with the inner side of the wall provides a construction in which the fluid channel is maximally flat (no obstructions, no discontinuities), so that the liquid can easily reach the sensitive surface of the microchip 10.

The terminals or bonding sites of the VIAs 14 at the back side of the sensor chip 10 are connected by a flip-chip like technology via bumps 104 to the conducting wires of a interconnection device, for example a flex foil 102. In the embodiment shown in FIG. 1, the flex foil 102 is disposed adjacent to the bottom wall 105 of the biosensor 100 and preferably fixed thereto (e.g. by gluing). The Figure also indicates that the VIAs 14 may be located at every location of the sensor chip 10 (not only at its borders) in order to realize feedthrough connections where necessary.

FIGS. 2 to 7 show various modifications of the biosensor 100 of FIG. 1. Note that in these Figures the reference numbers of identical or similar parts of the microfluidic devices differ in steps of 100 (the fluid channels have for example the reference numbers 106, 206, 306, 406, 506, 606 and 706). These components will not be described in detail for every Figure.

In the second embodiment of a biosensor 200 shown in FIG. 2, the terminals or bond pads at the bottom side of the sensor chip 10 are directly bonded with flip-chip like bumps 204 to the bonding pads at the front side of a signal processing chip 20. This measure realizes the shortest possible connection length from the sensor chip 10 to a preamplifier on the signal processing chip 20 and thus the largest detection bandwidth. Moreover, the signal processing chip 20 laterally extends beyond the sensor chip 10 allowing that bond pads on its front side are connected by a flip-chip bumps 207 to a flex foil 202 extending adjacent to the bottom wall 205 of the biosensor 200.

FIG. 3 shows a modified biosensor 300, wherein the signal processing chip 20 comprises VIAs 24 which lead from its front side to its back side. Their terminals at the back side can then be connected by flip-chip bumps 307 to the wires of a flex foil 302. Both the sensor chip 10 and the signal processing chip 20 may be held and sealed by a circumferential ring 303 of glue.

FIG. 4 shows a biosensor 400 with a sensor chip 10 and a signal processing chip 20 located besides each other on a flex foil 402 or a molded interconnection device (MID). In this case the signal processing chip 20 needs no VIAs but can be directly bonded to the flex foil 402 with a flip-chip technology.

In the biosensor 500 of FIG. 5, the thickness d (cf. FIG. 8) of the sensor chip 10 is reduced from 680 μm to e.g. 50 μm. This is realized by removing a part of the substrate 13 (cf. FIG. 8), e.g. by chemical-mechanical etching, and has the additional advantage that feedthrough VIAs can more easily be implemented because less substrate has to be pierced. While such a thin sensor chip may be used in any embodiment of the previous Figures, it particularly allows for the embodiment of the biosensor 500, in which the sensor chip is disposed inside the fluid channel 506. The bottom wall of the channel is realized by a flex foil 502 or a MID, to which the sensor chip 10 is attached by a watertight ring of glue 503. Electrical contacting between the flex foil 502 and the VIAs of the microchip 10 is achieved by flip-chip bumps 504. Due to the reduced chip-thickness, the unevenness in the flow channel 506 will be minimal. Optionally the chip may be mechanically supported by a support layer 508.

FIG. 6 shows a modification of the embodiment of FIG. 5, wherein the thin sensor chip 10 is integrated into the bottom wall 602 (flex foil or MID) of the biosensor 600. The further design is similar to that of FIG. 2, i.e. the back side of the sensor chip 10 is directly bonded to a signal processing chip 20 which in turn is bonded to the flex foil 602. Due to the reduced thickness of the sensor chip 10, the flex foil 602 can simultaneously constitute the bottom wall of the fluid channel 606. Mechanical supports may be added to the chip(s) and the flex foil to realize sufficient mechanical stiffness.

FIG. 7 depicts a further embodiment of the biosensor 700 which is similar to that of FIG. 1 besides the fact that the VIAs 714 are located at a lateral side of the substrate of the sensor chip 10. The corresponding bonding pads or terminals may therefore also be located at the lateral sides of the microchip 10 allowing to place the sensor chip 10 in a gapless way onto the bottom wall 702 of the device, thus further reducing the protrusion of the sensor into the fluid channel 706. The bond pads or terminals may be connected by wires 704′ to the wires of the flex foil 702, as shown on the left side of FIG. 7, or by flip-chip bumps 704, as shown on the right hand side of FIG. 7 (these two alternatives are only shown for illustrative purposes at the same microchip). The VIAs need not completely pierce through the substrate of the sensor chip. Both the wires 704′ and the microchip bumps 704 are preferably embedded in glue 703. If a conductive glue is used, the wires 704′ or bumps 704 may be omitted.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A microchip (10), comprising:
a) a substrate (13);
b) coupling circuits (11, 12) on a front side of the substrate (13), the coupling circuits (11, 12) being adapted to perform and process a wireless physical interaction;
c) at least one electrical feedthrough passage, called VIA (14, 714), that is embedded in the substrate (13) and that connects a component of the coupling circuits (11, 12) to an externally accessible terminal (15, 104, 204, 304, 404, 504, 604, 704) which is disposed at a location remote from the front side of the substrate (13).

2. The microchip (10) according to claim 1, characterized in that the coupling circuits implement a capacitive sensor, a light sensor, a current sensor, a voltage sensor and/or a magneto-electric sensor.

3. The microchip (10) according to claim 1, characterized in that the coupling circuits comprise circuits (11) for the generation of an electromagnetic field and/or circuits (12) for the detection of an electromagnetic field, particularly a Giant Magneto Resistance.

4. The microchip (10) according to claim 1, characterized in that the terminal (15, 104, 204, 304, 404, 504, 604, 704) of the VIA (14, 714) is located at the back side or at a lateral side of the substrate (13).

5. The microchip (10) according to claim 1, characterized in that the at least one terminal (204, 304, 604) is bonded to a second microchip, preferably to a signal processing chip (20).

6. The microchip (10) according to claim 5, characterized in that the second microchip (20) comprises at least one VIA (24).

7. The microchip (10) according to claim 1, characterized in that its thickness (d) ranges from 10 to 1000 μm, preferably from 30 to 60 μm.

8. A microfluidic device (100, 200, 300, 400, 500, 600, 700) with a sample chamber (106, 206, 306, 406, 506, 606, 706), particularly a biosensor, comprising a microchip (10) according to claim 1.

9. The microfluidic device (500, 700) according to claim 8, characterized in that the microchip (10) is attached to the inner side of a wall (502, 702) of the sample chamber (506, 706).

10. The microfluidic device (500) according to claim 9, characterized in that a mechanical support (508) is disposed between the microchip (10) and said wall (502).

11. The microfluidic device (100, 200, 300, 400, 600) according to claim 8, characterized in that it is integrated into a wall (105, 205, 305, 405, 602) of the sample chamber (106, 206, 306, 406, 606).

12. The microfluidic device (500, 600, 700) of claim 8, characterized in that at least one wall (502, 602, 702) of the sample chamber (506, 606, 706) is a molded interconnection device or a flex foil.

13. The microfluidic device (200, 300, 400, 600) according to claim 8, characterized in that it comprises a second microchip (20) which is connected to the first microchip (10) directly or via electrical leads (402).
